(19) United States
(12) Patent Application Publication
(10) Pub. No.: US 2014/0151880 A1
(43) Pub. Date: Jun. 5, 2014

(54) PACKAGE-ON-PACKAGE STRUCTURES

(71) Applicant: Marvell World Trade Ltd., St. Michael (BB)

(72) Inventors: Huahung Kao, San Jose, CA (US); Shiann-Ming Liou, Campbell, CA (US)

(73) Assignee: Marvell World Trade Ltd., St. Michael (BB)

(21) Appl. No.: 14/176,695

(22) Filed: Feb. 10, 2014

Related U.S. Application Data
(63) Continuation-in-part of application No. 13/584,027, filed on Aug. 13, 2012.
(60) Provisional application No. 61/763,285, filed on Feb. 11, 2013.
(60) Provisional application No. 61/525,521, filed on Aug. 19, 2011.

(51) Int. Cl. H01L 25/18; H01L 23/00; H01L 25/00

(52) U.S. Cl. CPC H01L 25/18; H01L 25/50; H01L 24/11; H01L 24/17
USPC 257/738; 438/108

(57) ABSTRACT

Embodiments of the present disclosure provide a package on package arrangement comprising a first package including a substrate layer including a top side, and a bottom side that is opposite to the top side, wherein the top side of the substrate layer defines a substantially flat surface, and a first die coupled to the bottom side of the substrate layer. The arrangement also comprises a second package including a plurality of rows of solder balls and at least one of one or both of an active component or a passive component. The second package is attached, via the plurality of rows of solder balls, to the substantially flat surface of the top side of the substrate layer of the first package. The active component and/or a passive component is attached to the substantially flat surface of the top side of the substrate layer of the first package.

### CROSS REFERENCE TO RELATED APPLICATIONS

This claims priority to U.S. Provisional Application No. 61/763,285, filed Feb. 11, 2013, the entire specification of which is incorporated herein by reference. This is also a continuation-in-part of U.S. patent application Ser. No. 13/584,027, filed Aug. 13, 2012, which claims priority to U.S. Provisional Application No. 61/525,521, filed Aug. 19, 2011, the entire specifications of which are incorporated herein by reference.

### TECHNICAL FIELD

Embodiments of the present disclosure relate to package on package (POP) structures, and more particularly to packaging arrangements that incorporate a base package with a die-down flipped structure.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Typically, with many multi-chip packaging arrangements, a packaging arrangement is arranged in one of either a package-on-package (PoP) arrangement, or a multi-chip module (MCM) arrangement. These packaging arrangements tend to be fairly thick (e.g., approximately 1.7 millimeters to 2.0 millimeters).

A PoP arrangement may include an integrated circuit that combines two or more packages on top of each other. For instance, a PoP arrangement may be configured with two or more memory device packages. A PoP arrangement may also be configured with mixed logic-memory stacking that includes logic in a bottom package and memory in a top package or vice versa.

Typically, a die associated with a package located on the bottom of a PoP arrangement (referred to herein as a “bottom package”) limits the footprint of a package located above the bottom package (referred to herein as a “top package”) to be a certain size. Additionally, such a configuration generally limits the top package to two rows of peripheral solder balls. An example of such a packaging arrangement 1100 is illustrated in FIG. 11 and includes a top package 1102 and a bottom package 1104. As can be seen, the bottom package 1104 includes a die 1106 attached to a substrate 1108 via an adhesive 1110. The die 1106 is coupled to the substrate 1108 via a wirebonding process with wires 1112. Solder balls 1114 are provided for coupling the packaging arrangement 1100 to another substrate (not illustrated) such as, for example, a printed circuit board (PCB). The top package 1102 includes a die 1116 coupled to a substrate 1116. Solder balls 1120 are provided to couple the top package 1102 to the bottom package 1104. The top package 1102 may include an enclosure 1122, generally in the form of an encapsulant, if desired. As can be seen, only two rows of solder balls 1120 can be provided due to the presence of the die 1106 and an enclosure 1124 (generally in the form of an encapsulant and which may or may not be included) of the bottom package 1104. Thus, top packages may be required to have larger sizes or footprints to avoid the die 1106 of bottom packages when a top package is attached to the bottom package. Such packaging arrangements 1100 can also present problems with clearance issues for the top package 1102 with respect to the die 1106 and/or enclosure 1124.

FIG. 11 illustrates another example of a packaging arrangement 1200 where a bottom package 1204 has been created with a Mold-Array-Process (MAP). The bottom package 1204 is similar to the bottom package 1104 of FIG. 11 and includes an encapsulant 1206. The encapsulant 1206 is generally etched to expose solder balls 1208. Alternatively, the encapsulant 1206 is etched and then solder balls 1208 are deposited within the openings 1210. Such a packaging arrangement 1200 once again only allows for the inclusion of two rows of solder balls 1120 around the periphery of the top package 1102 due to the presence of the die 1106 and the encapsulant 1206. Such packaging arrangements 1200 can also present problems with clearance issues for the top package 1102 with respect to the die 1106 and the encapsulant 1206, as well as alignment issues with respect to the openings 1210.

### SUMMARY

In various embodiments, the present disclosure provides a package on package arrangement comprising a first package including a substrate layer including (i) a top side, and (ii) a bottom side that is opposite to the top side, wherein the top side of the substrate layer defines a substantially flat surface, and a first die coupled to the bottom side of the substrate layer. The package on package arrangement also comprises a second package including a plurality of rows of solder balls and at least one of one or both of (i) an active component or (ii) a passive component. The second package is attached, via the plurality of rows of solder balls, to the substantially flat surface of the top side of the substrate layer of the first package. The at least one of one or both of (i) an active component or (ii) a passive component is attached to the substantially flat surface of the top side of the substrate layer of the first package.

In various embodiments, the present disclosure also provides a method comprising providing a first package including a substrate layer, wherein the substrate layer includes (i) a top side and (ii) a bottom side that is opposite to the top side, wherein the top side of the substrate layer defines a substantially flat surface, and wherein the first package further includes a first die coupled to the bottom side of the substrate layer. The method further comprises providing a second package having a plurality of rows of solder balls attached to a bottom surface of the second package, attaching, via the plurality of rows of solder balls of the second package, the second package to the substantially flat surface of the first package, and attaching at least one of one or both of (i) an active component or (ii) a passive component to the substantially flat surface of the top side of the substrate layer of the first package.

Various embodiments potentially include one or more of the following advantages. Packaging arrangements can provide increased pincount, in accordance with various embodiments described herein. Also, higher speeds may be realized for electronic devices using packaging arrangements in accordance with various embodiments described herein.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Embodiments herein are illustrated by way of example and not by way of limitation in the figures of the accompanying drawings.

FIG. 1A schematically illustrates an example packaging arrangement that includes an example die arrangement of a die-down flipped PoP structure.

FIG. 1B schematically illustrates the example packaging arrangement of FIG. 1A with a top package attached to a bottom package.

FIG. 2 schematically illustrates another example packaging arrangement that includes another example die arrangement of a die-down flipped PoP structure with exposed material to provide a path for thermal dissipation.

FIG. 3 schematically illustrates another example packaging arrangement that includes another example die arrangement of a die-down flipped PoP structure that is exposed, to provide a path for thermal dissipation.

FIG. 4 schematically illustrates another example packaging arrangement that includes another example die arrangement of a die-down flipped PoP structure with through-silicon vias (TSVs).

FIG. 5 schematically illustrates another example packaging arrangement that includes another example die arrangement of a die-down flipped PoP structure with an embedded printed circuit board (PCB) and/or an interposer.

FIG. 6 schematically illustrates another example packaging arrangement that includes another example die arrangement of a die-down flipped PoP structure with a PCB/interposer.

FIG. 7 is a process flow diagram of a method for making PoP structures described herein.

FIG. 8 schematically illustrates another example packaging arrangement that includes an example packaged device arrangement and passive and/or active electronic components.

FIG. 9 schematically illustrates another example packaging arrangement that includes multiple dies and passive and/or active electronic components.

FIG. 10 is another process flow diagram of a method for making PoP structures described herein.

FIG. 11 schematically illustrates an example PoP packaging arrangement.

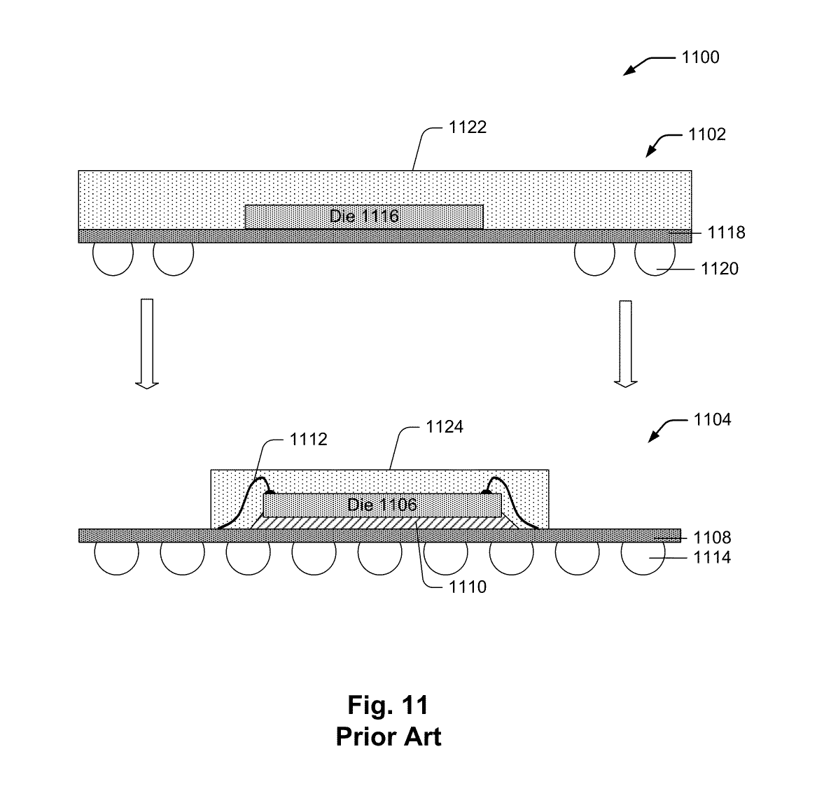

FIG. 12 schematically illustrates another example PoP packaging arrangement.

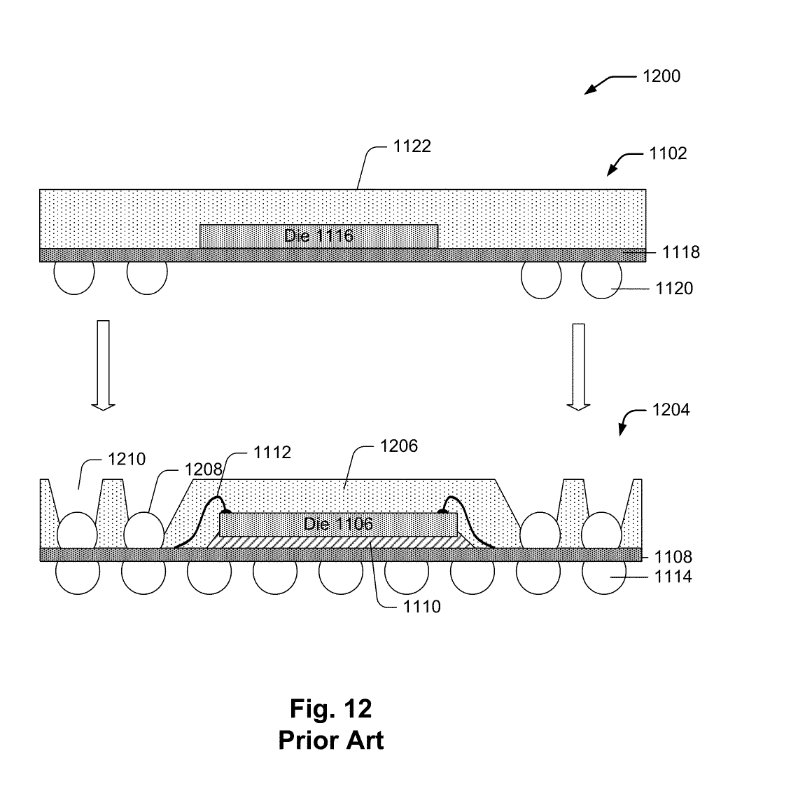

### DETAILED DESCRIPTION

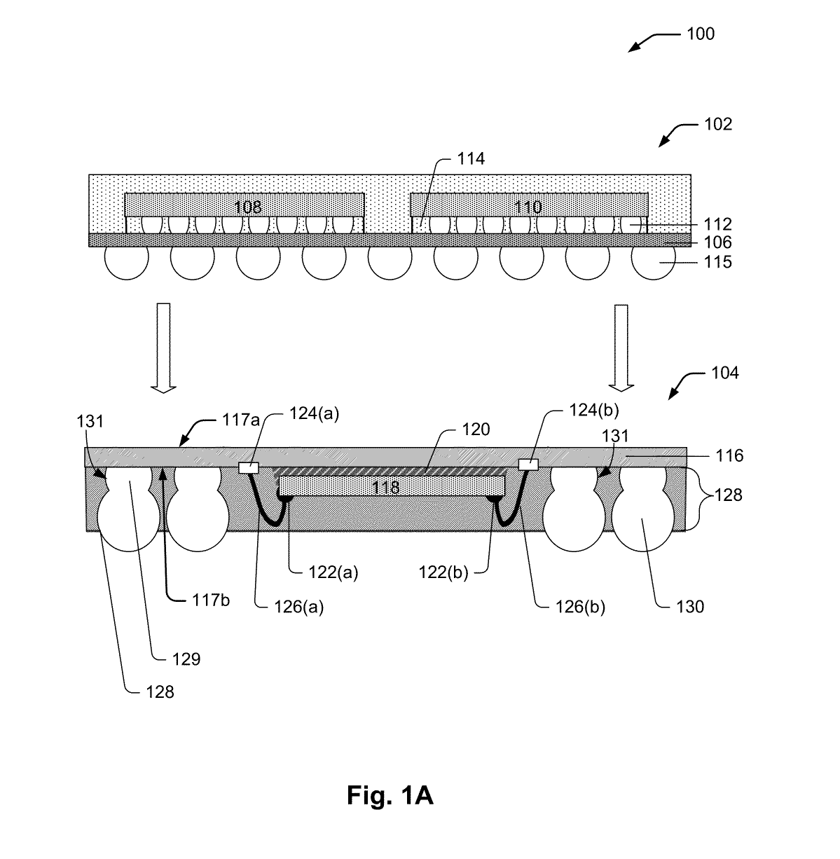

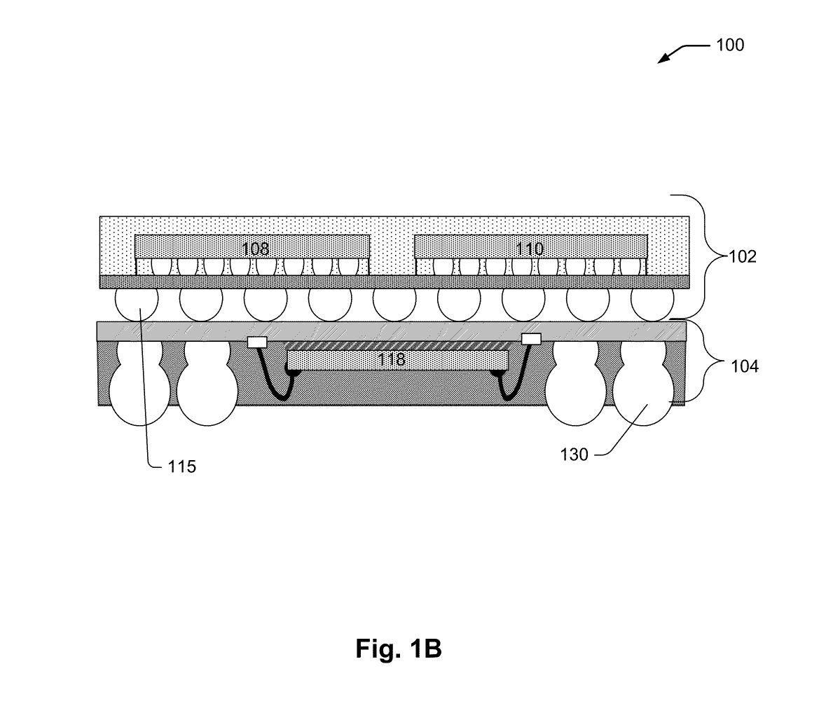

FIG. 1A illustrates a packaging arrangement 100 according to an embodiment where a package on package (PoP) packaging arrangement includes a top package 102 and a bottom package 104. For illustrative purposes, the packages are illustrated as separate items. The top package 102 includes a substrate layer 106. A die arrangement within the top package 102 may include a first die 108 and a second die 110, in which each die 108, 110 is attached to the substrate layer 106 via solder balls 112. This configuration may include underfill material 114 in space between the solder balls 112 and the substrate layer 106. The solder balls 112 are generally located at bond pads or contact areas (not illustrated). The dies 108, 110 can be coupled to the substrate layer 106 via a flip-chip operation. Alternatively, a wire bonding process and an adhesive layer (not illustrated) may be used to couple the dies 108, 110 to the substrate layer 106. Additionally, top package 102 may comprise two or more individual top packages 102 (not illustrated), where each individual top package 102 includes one or more dies.

In accordance with various embodiments, the first die 108 and the second die 110 are memory devices and, in accordance with an embodiment, the first die 108 and the second die 110 are mobile double data rate (mDDR) synchronous dynamic random access memory (DRAM) for mobile devices. Mobile DDR is also known as low power DDR. However, other types of memory devices may be utilized, including but not limited to a double data rate synchronous dynamic random-access memory (DDR SDRAM), a dynamic random access memory (DRAM), a NOR or a NAND Flash memory, a static random-access memory (SRAM), and the like.

In accordance with another embodiment, the top package 102 with the first die 108 and the second die 110 is directed towards application-specific products, and, in accordance with an embodiment, the first die 108 and/or the second die 110 may represent application-specific integrated circuits (ASICs) for a mobile device.

The top package 102 further includes a plurality of solder balls 115. The plurality of solder balls 115 may be attached to a bottom side of the substrate layer 106 of the top package 102. In the embodiment of FIG. 1A, the plurality of solder balls 115 forms a configuration for electrically and physically attaching or stacking the top package 102 on the bottom package 104.

For clarity, materials used within the top package 102 and other components within the top package 102 may not be illustrated and/or described in detail herein. Such materials and components are generally well-known in the art.

The bottom package 104 includes a substrate layer 116 that includes a top side 117a and a bottom side 117b. As shown in FIG. 1A, the top side 117a defines a substantially flat surface of the bottom package 104, i.e. a substantially smooth surface that is substantially free of grooves, bumps, indentations, valleys, etc. In one embodiment, the substantially flat surface of the top side 117a does not contain any components, which permits the top side 117a to receive (or support) various designs and selections of the top package 102. Thus, the flat top surface of the bottom package 104 provides a convenient way for the plurality of solder balls 115 of the top package 102 to attach to the bottom package 104, which allows for greater flexibility in designing top package 102 (or multiple individual top packages 102) and thereby, designing packaging arrangement 100.

The bottom package 104 includes a die 118 attached to the bottom side 117b of the substrate layer 116 via an adhesive layer 120 in a die-down flipped structure. In other embodiments, as will be further discussed herein, the die 118 may be attached to the bottom side 117b of the substrate layer 116 via solder balls.

In accordance with various embodiments, the die 118 may be a memory device, such as a mobile double data rate (mDDR) synchronous dynamic random access memory (DRAM) for mobile devices. Other types of memory devices may be utilized, including but not limited to a double data rate synchronous dynamic random-access memory (DDR SDRAM), a dynamic random access memory (DRAM), a NOR or a NAND Flash memory, a static random-access memory (SRAM), and the like. In accordance with another embodiment, the die 118 may be a logic device to create a mixed logic-memory stacking that includes logic on the bottom package 104 and memory on the top package 102.

The die 118 has surfaces that include one or more bond pads 122a, 122b. The one or more bond pads 122a, 122b generally comprise an electrically conductive material such as, for example, aluminum or copper. Other suitable materials can be used in other embodiments. The die 118 is coupled to one or more substrate pads 124a, 124b located on the substrate layer 116 via bonding wires 126a, 126b that are coupled to corresponding bond pads 122a, 122b. The die 118 may be affixed to the bottom package 104 by molding material. In other embodiments, the die 118 may electrically interconnect with the substrate layer 116 via flip-chip or conductive adhesives. The electrical signals of the die 118 can include, for example, input/output (I/O) signals and/or power/ground for integrated circuit (IC) devices (not illustrated) formed on the die 118.

In accordance with an embodiment, the bottom package 104 is created via a Mold-Array-Process (MAP). The bottom package 104 further includes an enclosure 128, generally in the form of an encapsulant. The enclosure 128 is etched to expose solder balls 129. Alternatively, the solder balls 129 are added into etched openings 131 of the enclosure 128 after etching the enclosure 128. Solder balls 130 are added to solder balls 129 and can be used to couple the packaging arrangement 100 to a substrate (not illustrated) such as, for example, a printed circuit board (PCB), another package, etc. Alternatively, single solder balls (combined solder balls 129 and solder balls 130) are added into the etched openings 131 after etching the enclosure 128. The solder balls 130 are generally at the sides or around the periphery of the bottom package 104, thereby forming a ball grid array (BGA).

For clarity, materials used within the bottom package 104 and other components within the bottom package 104 may not be illustrated and/or described in detail herein. Such materials and components are generally well-known in the art.

FIG. 1B illustrates the packaging arrangement 100 with the top package 102 attached to the bottom package 104. In the embodiment of FIGS. 1A and 1B, the plurality of solder balls 115 forms a configuration for electrically and physically attaching or stacking the top package 102 to the bottom package 104. As previously noted, top package 102 may comprise two or more individual top packages that are attached to the bottom package 104.

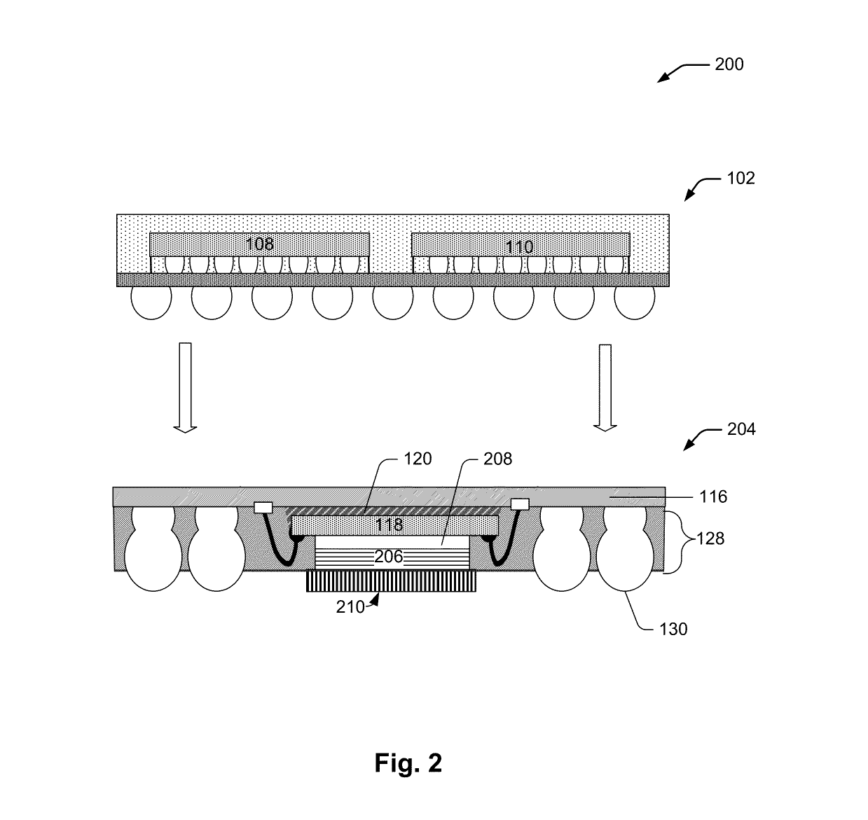

Additional embodiments of the present disclosure generally relate to packaging arrangements that include various embodiments of the bottom package 104 with a die-down flipped structure and are illustrated in FIGS. 2-6. For brevity, the components illustrated in FIGS. 1A and 1B that are the same as or similar to the components in FIGS. 2-7 are not discussed further herein.

FIG. 2 illustrates another embodiment of a packaging arrangement 200 that includes a top package 102 and a bottom package 204. In the embodiment of FIG. 2, a thermal conductive material 206 is included on a bottom side of the die 118. In an embodiment, the thermal conductive material 206 is attached to the bottom side of the die 118 via an adhesive layer 208. The thermal conductive material 206 includes, but is not limited to metal, silicon, or any material suitable for good thermal conductivity.

The bottom package 204 includes a thermal interface material (TIM) 210 coupled to the thermal conductive material 206. The TIM 210 includes, but is not limited to, a film, a grease composition, and underfill material. A film may be of an ultra-thin, thermally conductive material, which can be prepared by depositing an amorphous material. A grease composition may include a composition that has high thermal conductivity and excellent dispensation characteristics. A common TIM is a white-colored paste or thermal grease, typically silicone oil filled with aluminum oxide, zinc oxide, or boron nitride. Some types of TIMs use micronized or pulverized silver. Another type of TIM includes phase-change materials. Phase-change materials generally are solid at room temperature but liquefy and behave like grease at operating temperatures.

An underfill material may be chosen based on the desired physical properties. Thus, the thermal conductive material 206 provides a path for thermal dissipation to the TIM 210. The packaging arrangement 200 can be coupled to a substrate (not illustrated) such as, for example, a PCB or another packaging arrangement. A hole may be provided in the substrate to accommodate the TIM 210.

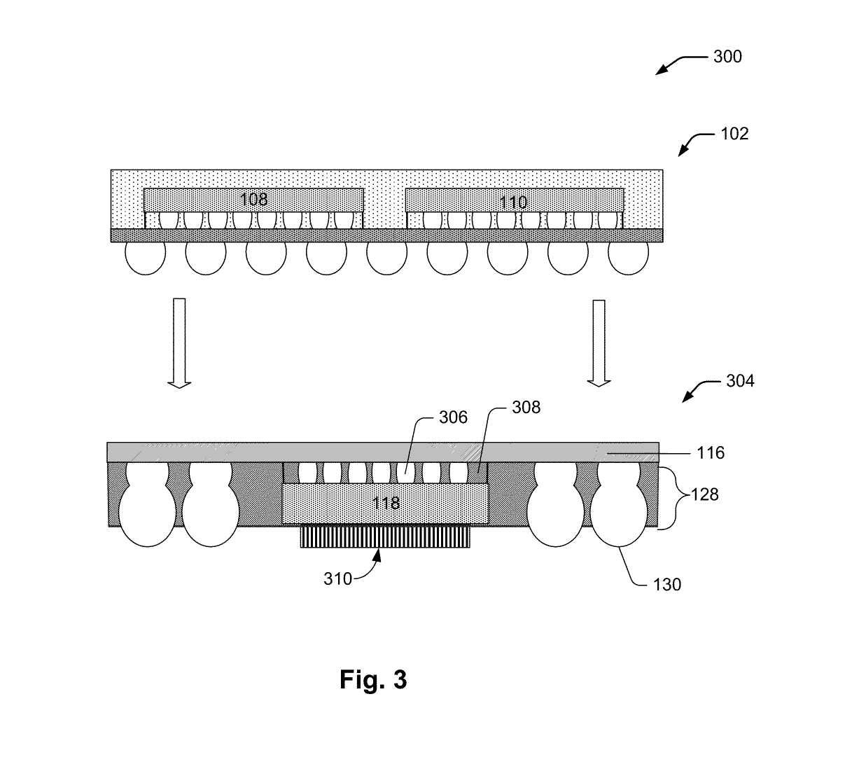

FIG. 3 illustrates an embodiment of a packaging arrangement 300 that includes a top package 102 and a bottom package 304. The die 118 is attached to the substrate layer 116 via solder balls 306. In accordance with various embodiments, underfill material 308 is provided between the die 118 and the substrate layer 116 among the solder balls 306. The underfill material 308 provides protection of the joints formed by the solder balls 306. It also prevents cracking and delamination of inner layers of the die 118. The underfill material 308 may be a high purity, low stress liquid epoxy. Generally, the larger the size of the solder balls 306, the less need there is for the underfill material 308.

The bottom package 304 includes a thermal interface material (TIM) 310 coupled to a backside of the die 118. The TIM 310 includes, but is not limited to, a film, a grease composition, and underfill material, as previously described. In the embodiment of FIG. 3, the backside of the die 118 is exposed. The exposed backside of the die 118 provides a path for thermal dissipation to the TIM 310. The packaging arrangement 300 can be coupled to a substrate (not illustrated) such as, for example, a PCB or another packaging arrangement. A hole may be provided in the substrate to accommodate the TIM 310.

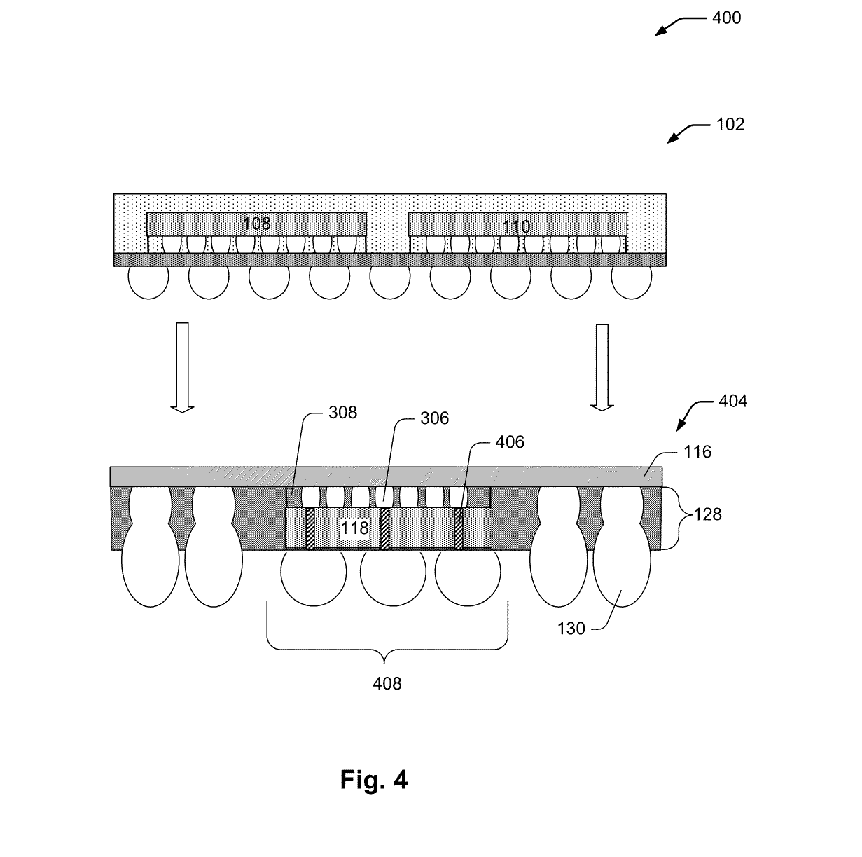

FIG. 4 illustrates an embodiment of a packaging arrangement 400 that includes a top package 102 and a bottom package 404. The die 118 is attached to the substrate layer 116 via solder bumps 306. Underfill material 308 is provided in a space located between the die 118 and the substrate layer 116 of the bottom package 404. The underfill material 308 provides protection of the joints formed by the solder balls 306.

In the embodiment of FIG. 4, the die 118 includes through-silicon vias (TSVs) 406. In an embodiment, the die 118 may be recessed within the enclosure 128 to help expose the backside of the die 118. The TSVs 406 are vertical electrical connections vias (Vertical Interconnect Access) that pass through the die 118 to the solder balls 306. In an embodiment, the bottom package 404 includes additional solder balls 408 attached to the bottom package 404. The additional solder balls 408 may be used for, for example, ground/power and input/outputs.

The one or more TSVs 406 are electrically coupled to bond pads (not illustrated) and are generally filled with an electrically conductive material, e.g., copper, to route electrical signals through the die 118. The TSVs 406 tend to provide improved performance with respect to bondwires as the density of the vias is substantially higher and the length of the connections is shorter in comparison to bondwires. The exposed backside of the die 118 provides for thermal dissipation of the bottom package 404. Thus, the packaging arrangement 400 can provide increased pincount and higher speeds for electronic devices using the packaging arrangement 400.

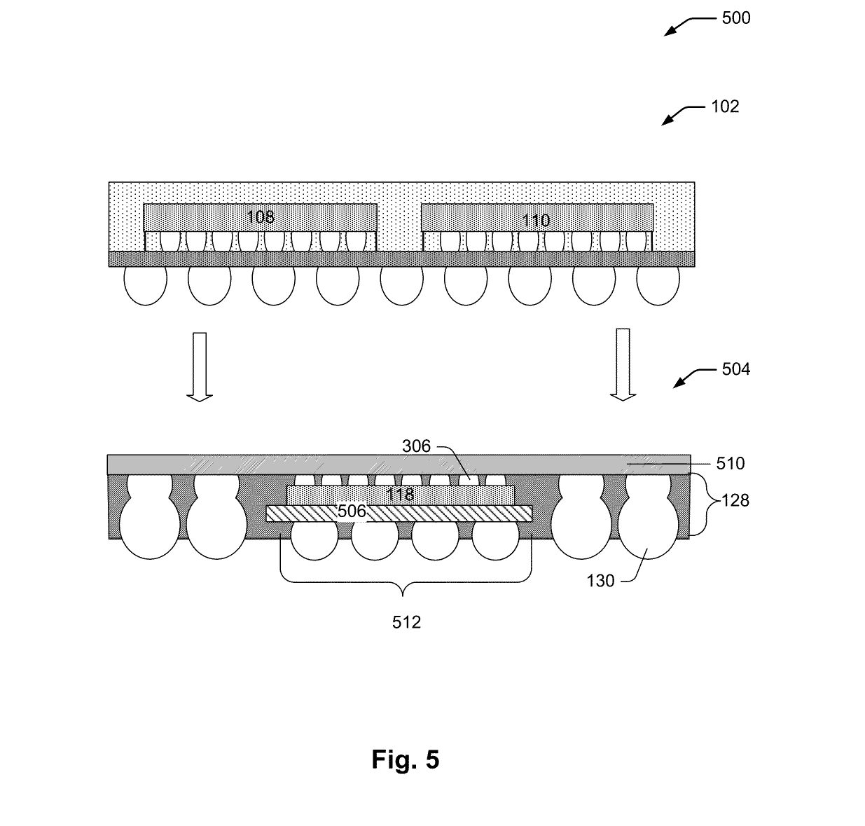

FIG. 5 illustrates an embodiment of a packaging arrangement 500 that includes a top package 102 and a bottom package 504. The die 118 is attached to the substrate layer 510 via solder bumps 306.

In the embodiment of FIG. 5, the bottom package 504 includes one or more PCBs and/or interposers 506 attached to the bottom side of the die 118. According to various embodiments, the PCB/interposer 506 is bonded to the die 118 using a thermal compression process or a solder reflow process. That is, one or more electrically conductive structures (e.g., pillars, bumps, pads, redistribution layer) are formed on the PCB/interposer 506 and the die 118 to form a bond between the PCB/interposer 506 and the die 118.

In some embodiments, the die 118 and the PCB/interposer 506 both comprise a material (e.g., silicon) having the same or similar coefficient of thermal expansion (CTE). Using a material having the same or similar CTE for the die 118 and the PCB/interposer 506 reduces stress associated with heating and/or cooling mismatch of the materials.

The PCB/interposer 506 provides a physical buffer, support, and strengthening agent to the die 118, particularly during the formation of the one or more layers to embed the die 118 in the enclosure 128. That is, the die 118 coupled to the PCB/interposer 506 as described herein provides a protected integrated circuit structure that is more structurally resilient than the die 118 alone to stresses associated with fabricating the enclosure 128, resulting in improved yield and reliability of the bottom package 504.

In an embodiment, the bottom package 504 includes additional solder balls 512. The additional solder balls 512 attached to the PCB/interposer 506 may be used for, for example, ground/power and input/outputs.

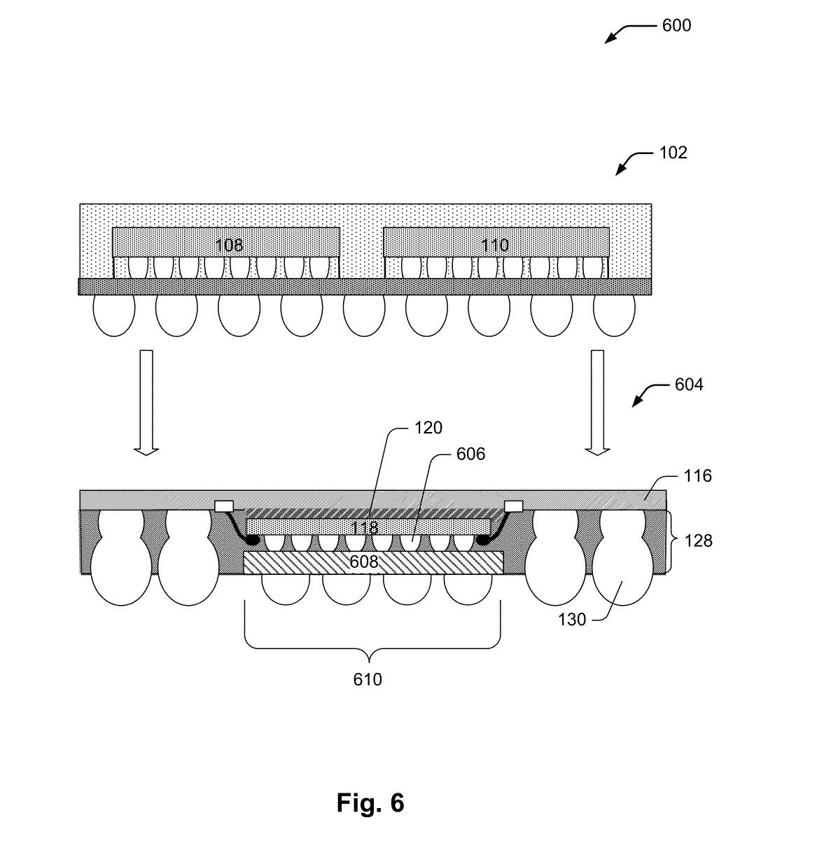

FIG. 6 illustrates an embodiment of a packaging arrangement 600 that includes a top package 102 and a bottom package 604. The die 118 is attached to the substrate layer 116 via the adhesive layer 120. As illustrated, the die 118 is coupled to the substrate layer 116 via a wire bonding process.

Solder bumps 606 are attached to the bottom side of the die 118. A PCB or an interposer 608 is attached to the solder balls 606. In an embodiment, the PCB/interposer 608 may be exposed or recessed. In an embodiment, the bottom package 604 includes additional solder balls 610. The additional solder balls 610 may be used for, for example, ground/power and input/outputs. The embodiment of FIG. 6 can allow for additional pincount and provides a path via the PCB/interposer 608 for thermal dissipation of the bottom package 604.

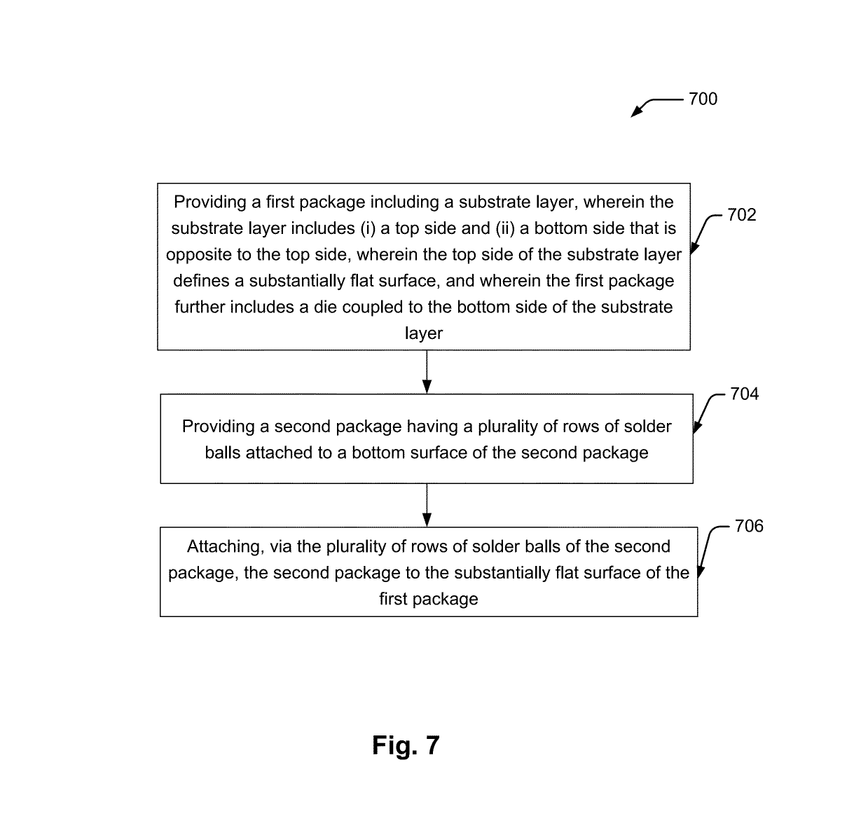

FIG. 7 illustrates an example method 700, in accordance with an embodiment of the present disclosure. At 702, the method 700 includes providing a first package including a substrate layer, wherein the substrate layer includes (i) a top side and (ii) a bottom side that is opposite to the top side, wherein the top side of the substrate layer defines a substantially flat surface, and wherein the first package further includes a die coupled to the bottom side of the substrate layer.

At 704, the method 700 includes providing a second package having a plurality of rows of solder balls attached to a bottom surface of the second package.

At 706, the method 700 includes attaching, via the plurality of rows of solder balls of the second package, the second package to the substantially flat surface of the first package.

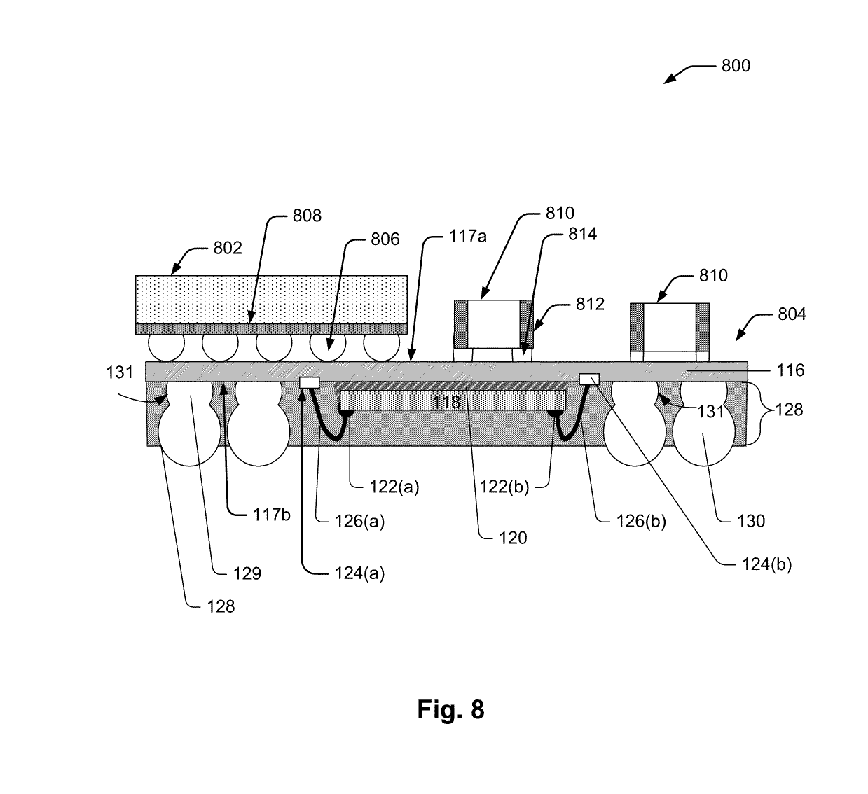

FIG. 8 illustrates a packaging arrangement 800 that includes a bottom package 804. As can be seen, the bottom package 804 is illustrated as being arranged the same as or similar to the bottom package 104 illustrated in FIGS. 1A and 1B. However, it is to be noted that the bottom package 804 can be arranged the same as or similar to the bottom packages 204, 304, 404, 504 and 604 as illustrated in FIGS. 2-6 if desired. For brevity, the components illustrated in FIGS. 1A and 1B and described with respect to the bottom package 104 are not discussed further herein.

The packaging arrangement 800 includes one or more packaged devices 802 that can be coupled via solder balls 806 to the top side 117a of the substrate layer 116 of the bottom package 804. The packaged device 802 may optionally include a substrate layer 808 on which various components and/or dies (not illustrated) included with packaged device 802 can be attached via various methods to create packaged device 802. Thus, the packaged device 802 may include one or more dies (not illustrated) that are memory devices. For example, the package device may be similar to the top package 102 illustrated in FIGS. 1-6. The packaged device 802 may include one or more dies (not illustrated) in the form of mobile double data rate (mDDR) synchronous dynamic random access memory (DRAM) for mobile devices. Mobile DDR is also known as low power DDR. However, other types of memory devices may be utilized, including, but not limited to, a double data rate synchronous dynamic random-access memory (DDR SDRAM), a dynamic random access memory (DRAM), a NOR or a NAND Flash memory, a static random-access memory (SRAM), and the like. Alternatively, one or more dies of the packaged device 802 may represent application specific integrated circuits (ASICs) for a mobile device.

The packaging arrangement 800 further includes one or more passive and/or active electronic components 810. The passive and/or active electronic components 810 can be attached to the top side 117a of the substrate 116 in any suitable manner. For example, the passive and/or active electronic components 810 can be attached to the top side 117a of the substrate 116 via leads 812 and solder 814. Examples of passive components 810 include, but are not limited to, capacitors, resistors, conductors, transformers, transducers, censors, and antennas. Another example of passive components includes, but is not limited to networks, e.g., a resistor capacitor (RC) circuit and an inductor capacitor (LC) circuit. Examples of active components 810 include, but are not limited to, semiconductor dies, integrated circuits, diodes (e.g., light emitting diodes (LEDs), laser diodes, etc.), optoelectronic devices and power sources. Signals from the packaged device 802 and/or the passive/active electronic components 810 can be routed through the substrate 116. The packaging arrangement 800 can include multiple bottom packages 804 arranged on top of one another, if desired. The multiple bottom packages 804 can be arranged the same as one another or differently from one another.

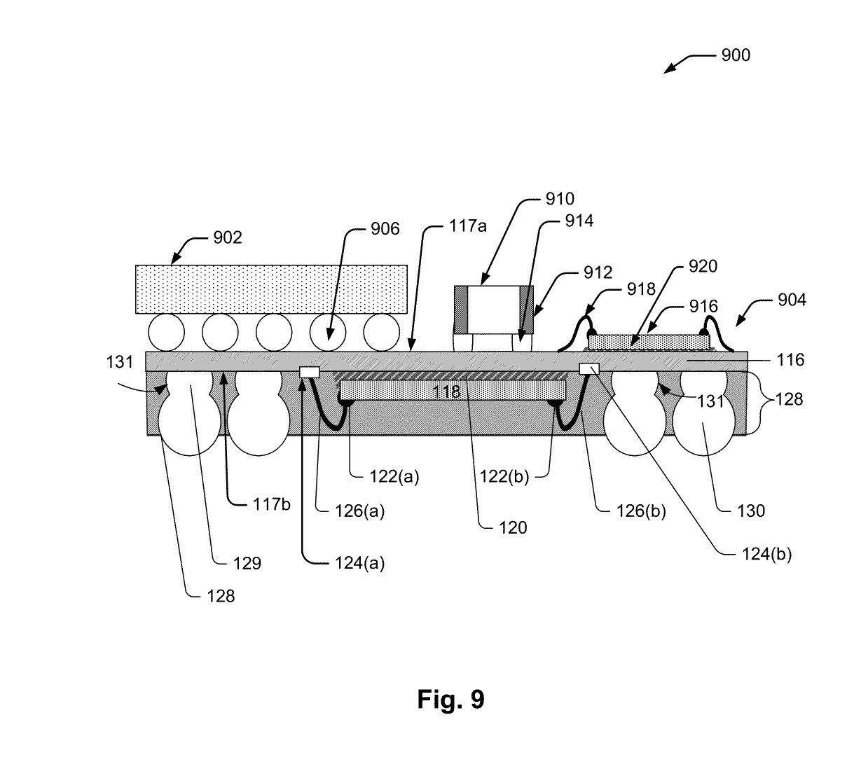

FIG. 9 illustrates another example of a packaging arrangement 900 that is similar to packaging arrangement 800 of FIG. 8. Once again, the packaging arrangement 900 is illustrated as including a bottom package 904 that is arranged the same as or similar to the bottom package 104 illustrated in FIGS. 1A and 1B. The packaging arrangement 904 can be arranged the same as or similar to the bottom packages 204, 304, 404, 504 and 604 illustrated in FIGS. 2-6 if desired. For brevity, the components illustrated in FIGS. 1A and 1B and described with respect to the bottom package 104 are not discussed further herein.

The packaging arrangement 900 includes a die 902 that is flip chip attached to the top side 117a of the substrate 116 of the bottom package 904 with solder balls 906. One or more passive and/or active components 910 are attached to the top side 117a of the substrate 116 of bottom package 904. The passive and/or active electronic components 910 can be attached to the top side 117a of the substrate 116 in any suitable manner. For example, the passive and/or active electronic components 910 can be attached to the top side 117a of the substrate 116 via leads 912 and solder 914. Examples of passive components 910 include, but are not limited to, capacitors, resistors, conductors, transformers, transducers, censors, and antennas. Another example of passive components includes, but is not limited to networks, e.g., a resistor capacitor (RC) circuit and an inductor capacitor (LC) circuit. Examples of active components 910 include, but are not limited to, semiconductor dies, integrated circuits, diodes (e.g., light emitting diodes (LEDs), laser diodes, etc.), optoelectronic devices and power sources.

The packaging arrangement 900 also includes a die 916 that is attached to the top side 117a of the substrate 116 of bottom package 904. The die 912 is wire bonded via wires 918 to the top side 117a of the substrate 116 of the bottom package 904. An adhesive layer 920 may be utilized to attach the die 916 to the top side 117a of the substrate 116. Signals from the die 902, the passive/active electronic components 910 and/or the die 916 can be routed through the substrate 116 of the bottom package 904. The packaging arrangement 900 can include multiple bottom packages 904 arranged on top of one another, if desired. The multiple bottom packages 904 can be arranged the same as one another or differently from one another.

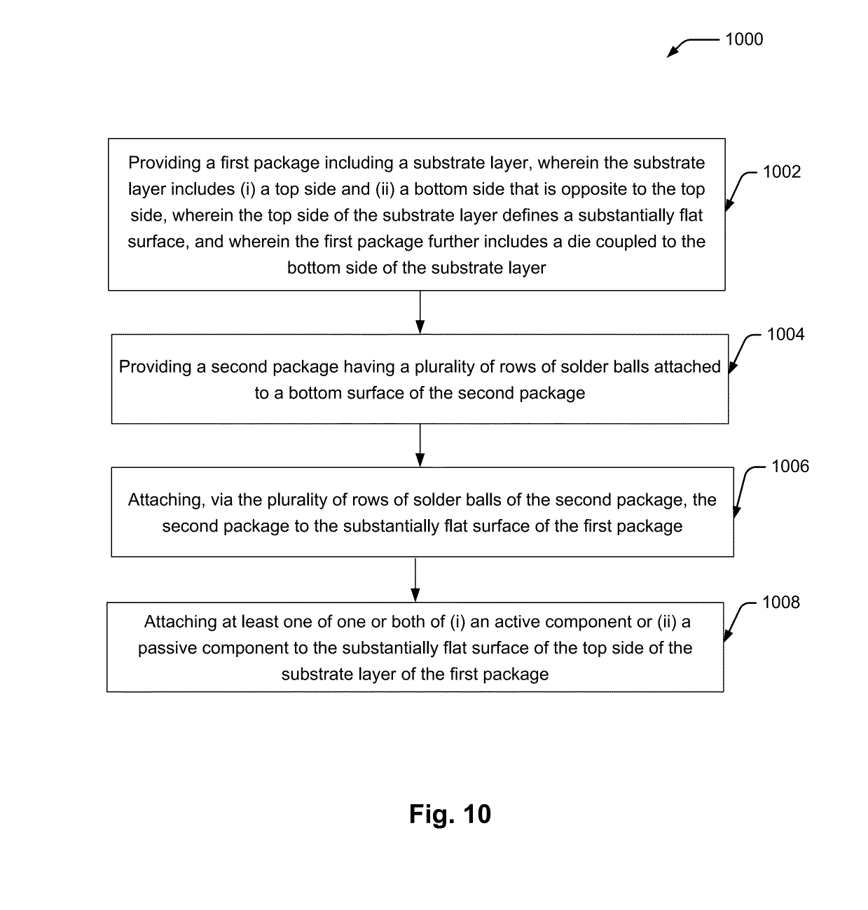

FIG. 10 illustrates an example method 1000, in accordance with an embodiment of the present disclosure. At 1002, the method 1000 includes providing a first package including a substrate layer, wherein the substrate layer includes (i) a top side and (ii) a bottom side that is opposite to the top side, wherein the top side of the substrate layer defines a substantially flat surface, and wherein the first package further includes a die coupled to the bottom side of the substrate layer.

At 1004, the method 1000 includes providing a second package having a plurality of rows of solder balls attached to a bottom surface of the second package.

At 1006, the method 1000 includes attaching, via the plurality of rows of solder balls of the second package, the second package to the substantially flat surface of the first package.

At 1008, the method 1000 includes attaching at least one of one or both of (i) an active component or (ii) a passive component to the substantially flat surface of the top side of the substrate layer of the first package.

The description may use perspective-based descriptions such as up/down, over/under, and/or, or top/bottom. Such descriptions are merely used to facilitate the discussion and are not intended to restrict the application of embodiments described herein to any particular orientation.

For the purposes of the present disclosure, the phrase “A/B” means A or B. For the purposes of the present disclosure, the phrase “A and/or B” means “(A), (B), or (A and B).” For the purposes of the present disclosure, the phrase “at least one of A, B, and C” means “(A), (B), (C), (A and B), (A and C), (B and C), or (A, B and C).” For the purposes of the present disclosure, the phrase “(A)B” means “(B) or (AB)” that is, A is an optional element.

Various operations are described as multiple discrete operations in turn, in a manner that is most helpful in understanding the claimed subject matter. However, the order of description should not be construed as to imply that these operations are necessarily order-dependent. In particular, these operations may not be performed in the order of presentation. Operations described may be performed in a different order than the described embodiment. Various additional operations may be performed and/or described operations may be omitted in additional embodiments.

The description uses the phrases “in an embodiment,” “in embodiments,” or similar language, which may each refer to one or more of the same or different embodiments. Furthermore, the terms “comprising,” “including,” “having,” and the like, as used with respect to embodiments of the present disclosure, are synonymous.

The terms chip, integrated circuit, monolithic device, semiconductor device, die, and microelectronic device are often used interchangeably in the microelectronics field. The present invention is applicable to all of the above as they are generally understood in the field.

Further aspects of the present invention relate to one or more of the following clauses.

The package on package arrangement further comprises a second die attached to the substantially flat surface of the top side of the substrate layer of the first package.

The second die is wire bonded to the substantially flat surface of the top side of the substrate layer of the first package.

The second die is attached to the substantially flat surface of the top side of the substrate layer of the first package via a flip-chip process.

The package on package arrangement further comprises an adhesive layer located between the first die and the substrate layer. The adhesive layer attaches the first die to the bottom side of the substrate layer of the second package.

The package on package arrangement further comprises a bond pad located on the bottom side of the first die, and a substrate pad located on the bottom side of the substrate layer of the second package. The bond pad of the die is coupled, via a wire, to the substrate pad of the substrate layer to route electrical signals of the first die.

The plurality of rows of solder balls comprises first solder balls and the package on package arrangement further comprises second solder balls attached to the bottom side of the substrate layer to electrically connect the first die to the substrate layer of the second package, and an underfill material located between the second solder balls and the substrate layer of the second package.

The plurality of rows of solder balls comprises first solder balls and the package on package arrangement further comprises second solder balls attached to a bottom side of the second package, and the second solder balls are located around a periphery of the second package to thereby form a ball grid array.

The plurality of rows of solder balls comprises first solder balls. The substrate layer comprises a first substrate layer. The first package further comprises a second die arranged next to the first die. Each of the first die and the second die is connected to a second substrate layer in the first package via second solder balls.

The package on package arrangement further comprises thermal interface material attached to a bottom side of the first die.

The package on package arrangement further comprises thermal conductive material attached to the thermal interface material.

The thermal interface material comprises one of a film, a grease composition, or an underfill material.

One of (i) an interposer or (ii) a printed circuit board is attached to a bottom side of the die.

The plurality of rows of solder balls comprises a first plurality of rows of solder balls, the package on package arrangement further comprises a third package including a second plurality of rows of solder balls, the first package is attached, via the first plurality of rows of solder balls, to the substantially flat surface of the second package, and the third package is attached, via the second plurality of rows of solder balls, to the substantially flat surface of the second package.

The plurality of rows of solder balls comprises first solder balls and the package on package arrangement further comprises second solder balls attached to the bottom side of the substrate layer and a top side of the first die, and a plurality of through-silicon vias located in the first die, wherein the plurality of through-silicon vias respectively extend between at least some of the second solder balls, and a plurality of third solder balls that are attached to a bottom side of the bottom package.

The method further comprises attaching a second die to the substantially flat surface of the top side of the substrate layer of the first package.

Attaching the first die to the bottom side of the substrate layer comprises attaching the first die to the bottom side of the substrate layer via an adhesive layer.

The plurality of rows of solder balls comprises first solder balls and the attaching the first die to the bottom side of the substrate layer comprises attaching the first die to the bottom side of the substrate layer via second solder balls.

The method further comprises providing underfill material between space located (i) among the second solder balls and (ii) between the first die and the bottom side of the substrate layer of the first package.

The method further comprises providing a bond pad on the first die, wherein the bond pad is positioned on a bottom side of the first die; providing a substrate pad on the substrate layer, wherein the substrate pad is positioned on the bottom side of the substrate layer of the first package; and coupling, via a wire bonding process, the bond pad on the first die to the substrate pad on the substrate layer to thereby route electrical signals of the first die.

The plurality of rows of solder balls comprises first solder balls and the method further comprises attaching second solder balls to a bottom side of the first package, wherein the second solder balls are positioned on a right side and a left side of the first package.

The method further comprises attaching a thermal interface material to a bottom side of the first die.

The plurality of rows of solder balls comprises first solder balls and the method further comprises attaching second solder balls on the bottom side of the substrate layer; attaching the first die to the bottom side of the substrate layer via the second solder balls; and providing through-silicon vias in the first die to connect the second solder balls to third solder balls attached to a bottom side of the first package.

The plurality of rows of solder balls comprises first solder balls and the method further comprises attaching second solder balls to a bottom side of the first die; and coupling one of (i) an interposer or (ii) a printed circuit board to the second solder balls.

The plurality of rows of solder balls comprises a first plurality of rows of solder balls, and the method further comprises providing a third package having a second plurality of rows of solder balls attached to a bottom surface of the third package, and attaching, via the second plurality of rows of solder balls, the third package to the substantially flat surface of the first package.

Although certain embodiments have been illustrated and described herein, a wide variety of alternate and/or equivalent embodiments or implementations calculated to achieve the same purposes may be substituted for the embodiments illustrated and described without departing from the scope of the present disclosure. This disclosure is intended to cover any adaptations or variations of the embodiments discussed herein. Therefore, it is manifestly intended that embodiments described herein be limited only by the claims and the equivalents thereof.

What is claimed is:

1. A package on package arrangement comprising:
a first package including
a substrate layer including (i) a top side, and (ii) a bottom side that is opposite to the top side, wherein the top side of the substrate layer defines a substantially flat surface, and
a first die coupled to the bottom side of the substrate layer;
a second package including a plurality of rows of solder balls; and
at least one of one or both of (i) an active component or (ii) a passive component,
wherein the second package is attached, via the plurality of rows of solder balls, to the substantially flat surface of the top side of the substrate layer of the first package, and
wherein the at least one of one or both of (i) an active component or (ii) a passive component is attached to the substantially flat surface of the top side of the substrate layer of the first package.

2. The package on package arrangement of claim 1, further comprising:
a second die attached to the substantially flat surface of the top side of the substrate layer of the first package.

3. The package on package arrangement of claim 2, wherein:
the second die is wire bonded to the substantially flat surface of the top side of the substrate layer of the first package.

4. The package on package arrangement of claim 2, wherein:
the second die is attached to the substantially flat surface of the top side of the substrate layer of the first package via a flip-chip process.

5. The package on package arrangement of claim 1, further comprising:
an adhesive layer located between the first die and the substrate layer,
wherein the adhesive layer attaches the first die to the bottom side of the substrate layer of the second package.

6. The package on package arrangement of claim 1, further comprising:
a bond pad located on the bottom side of the first die; and
a substrate pad located on the bottom side of the substrate layer of the second package,
wherein the bond pad of the die is coupled, via a wire, to the substrate pad of the substrate layer to route electrical signals of the first die.

7. The package on package arrangement of claim 1, wherein the plurality of rows of solder balls comprises first solder balls and the package on package arrangement further comprises:
second solder balls attached to the bottom side of the substrate layer to electrically connect the first die to the substrate layer of the second package; and
an underfill material located between the second solder balls and the substrate layer of the second package.

8. The package on package arrangement of claim 1, wherein the plurality of rows of solder balls comprises first solder balls and the package on package arrangement further comprises:
second solder balls attached to a bottom side of the second package; and
the second solder balls are located around a periphery of the second package to thereby form a ball grid array.

9. The package on package arrangement of claim 1, wherein:
the plurality of rows of solder balls comprises first solder balls;
the substrate layer comprises a first substrate layer;
the first package further comprises a second die arranged next to the first die; and
each of the first die and the second die is connected to a second substrate layer in the first package via second solder balls.

10. The package on package arrangement of claim 1, further comprising:
thermal interface material attached to a bottom side of the first die.

11. The package on package arrangement of claim 10, further comprising:
thermal conductive material attached to the thermal interface material.

12. The package on package arrangement of claim 11, wherein the thermal interface material comprises one of a film, a grease composition, or an underfill material.

13. The package on package arrangement of claim 1, further comprising:
one of (i) an interposer or (ii) a printed circuit board attached to a bottom side of the die.

14. The package on package arrangement of claim 1, wherein:
the plurality of rows of solder balls comprises a first plurality of rows of solder balls;
the package on package arrangement further comprises a third package including a second plurality of rows of solder balls;
the first package is attached, via the first plurality of rows of solder balls, to the substantially flat surface of the second package; and
the third package is attached, via the second plurality of rows of solder balls, to the substantially flat surface of the second package.

15. The package on package arrangement of claim 1, wherein the plurality of rows of solder balls comprises first solder balls and the package on package arrangement further comprises:
second solder balls attached to the bottom side of the substrate layer and a top side of the first die; and
a plurality of through-silicon vias located in the first die, wherein the plurality of through-silicon vias respectively extend between
at least some of the second solder balls, and
a plurality of third solder balls that are attached to a bottom side of the bottom package.

16. A method comprising:
providing a first package including a substrate layer, wherein the substrate layer includes (i) a top side and (ii) a bottom side that is opposite to the top side, wherein the top side of the substrate layer defines a substantially flat surface, and wherein the first package further includes a first die coupled to the bottom side of the substrate layer;
providing a second package having a plurality of rows of solder balls attached to a bottom surface of the second package;
attaching, via the plurality of rows of solder balls of the second package, the second package to the substantially flat surface of the first package; and
attaching at least one of one or both of (i) an active component or (ii) a passive component to the substantially flat surface of the top side of the substrate layer of the first package.

17. The method of claim 16, further comprising:
attaching a second die to the substantially flat surface of the top side of the substrate layer of the first package.

18. The method of claim 17, wherein the second die is wire bonded to the substantially flat surface of the top side of the substrate layer of the first package.

19. The method of claim 17, wherein the second die is attached to the substantially flat surface of the top side of the substrate layer of the first package via a flip-chip process.

20. The method of claim 16, wherein the attaching the first die to the bottom side of the substrate layer comprises attaching the first die to the bottom side of the substrate layer via an adhesive layer.

21. The method of claim 16, wherein the plurality of rows of solder balls comprises first solder balls and the attaching the first die to the bottom side of the substrate layer comprises attaching the first die to the bottom side of the substrate layer via second solder balls.

22. The method of claim 21, further comprising:
providing underfill material between space located (i) among the second solder balls and (ii) between the first die and the bottom side of the substrate layer of the first package.

23. The method of claim 16, further comprising:
providing a bond pad on the first die, wherein the bond pad is positioned on a bottom side of the first die;
providing a substrate pad on the substrate layer, wherein the substrate pad is positioned on the bottom side of the substrate layer of the first package; and
coupling, via a wire bonding process, the bond pad on the first die to the substrate pad on the substrate layer to thereby route electrical signals of the first die.

24. The method of claim 16, wherein the plurality of rows of solder balls comprises first solder balls and the method further comprises:
attaching second solder balls to a bottom side of the first package,
wherein the second solder balls are positioned on a right side and a left side of the first package.

25. The method of claim 16, further comprising:
attaching a thermal interface material to a bottom side of the first die.

26. The method of claim 16, wherein the plurality of rows of solder balls comprises first solder balls and the method further comprises:
attaching second solder balls on the bottom side of the substrate layer;
attaching the first die to the bottom side of the substrate layer via the second solder balls; and
providing through-silicon vias in the first die to connect the second solder balls to third solder balls attached to a bottom side of the first package.

27. The method of claim 16, wherein the plurality of rows of solder balls comprises first solder balls and the method further comprises:
attaching second solder balls to a bottom side of the first die; and
coupling one of (i) an interposer or (ii) a printed circuit board to the second solder balls.

28. The method of claim 16, wherein:
the plurality of rows of solder balls comprises a first plurality of rows of solder balls; and
the method further comprises
providing a third package having a second plurality of rows of solder balls attached to a bottom surface of the third package, and
attaching, via the second plurality of rows of solder balls, the third package to the substantially flat surface of the first package.
